(19) United States
(12) Patent Application Publication
(10) Pub. No.: US 2014/0092543 A1
(43) Pub. Date: Apr. 3, 2014

(54) KEYBOARD INTEGRATED NFC ANTENNA

(71) Applicants: Songnan Yang, San Jose, CA (US); Hong Wong, Portland, OR (US); Ulun Karacaoglu, San Diego, CA (US); Bin Xiao, San Ramon, CA (US); Changsong Sheng, Shanghai (CN)

(72) Inventors: Songnan Yang, San Jose, CA (US); Hong Wong, Portland, OR (US); Ulun Karacaoglu, San Diego, CA (US); Bin Xiao, San Ramon, CA (US); Changsong Sheng, Shanghai (CN)

(21) Appl. No.: 13/629,807

(22) Filed: Sep. 28, 2012

(51) Int. Cl. H05K 9/00; G06F 1/16

(52) U.S. Cl. 361/679.08; 361/816

(57) ABSTRACT

A metal baseboard with a planar shape which is placed close to a Near Field Communication (NFC) radio antenna may be configured with a number of slots in the metal. These slots may disrupt the eddy current that would otherwise be induced in the metal by magnetic emissions emanating from the NFC antenna. The reduction in eddy current that results from these slots may reduce the severe attenuation of the signal that would otherwise be caused by the metal. In general, each slot may run approximately perpendicular to the direction of the expected eddy current. This may be approximated by having many of the slots each run perpendicular to the nearest part of the antenna wiring.

### BACKGROUND

Near Field Communication (NFC) is a communications technique that uses the magnetic portion of the transmitted electromagnetic field. It is being incorporated in many portable devices as a form of very-short-distance communication. However, magnetic flux can be heavily absorbed by metal, and the induced eddy current in the metal reduces the signal strength even more. Many of the present varieties of very thin notebook computers are manufactured with a metal chassis and also with other metal parts which are largely planar in shape. This provides additional structural strength, which can reduce damage caused by the flexing of the chassis in everyday use. However, the metal chassis and other internal metal parts can create problems for the NFC wireless communications functions. NFC antennas for such communication are generally placed inside the chassis, since external antennas may be unsightly and are subject to physical damage. To avoid the signal attenuation problem caused by the metal, NFC antennas may be placed under a hole in the metal chassis (e.g., under the non-metal area created for the keyboard). But internal metal parts that require a certain level of structural strength may not be readily adaptable for cutting holes that are large enough for an NFC antenna.

### BRIEF DESCRIPTION OF THE DRAWINGS

Some embodiments of the invention may be better understood by referring to the following description and accompanying drawings that are used to illustrate embodiments of the invention. In the drawings:

FIG. 1A shows a communications device, according to an embodiment of the invention.

FIG. 1B shows functional components within a wireless communications device, according to an embodiment of the invention.

FIG. 2 shows some components of a low profile keyboard assembly, according to an embodiment of the invention.

FIG. 3 shows a baseboard and nearby antenna, according to an embodiment of the invention.

FIGS. 4A, 4B show two different patterns of slots created in a planar metal sheet, according to two embodiments of the invention.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure an understanding of this description.

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics. Further, some embodiments may have some, all, or none of the features described for other embodiments.

In the following description and claims, the terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not have intervening physical or electrical components between them.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The term “wireless” may be used to describe circuits, devices, systems, methods, techniques, communications channels, etc., that communicate data by using modulated electromagnetic radiation through a non-solid medium. A wireless device may comprise at least one antenna, at least one radio, at least one memory, and at least one processor, where the radio(s) transmits signals through the antenna that represent data and receives signals through the antenna that represent data, while the processor(s) may process the data to be transmitted and the data that has been received. The processor(s) may also process other data which is neither transmitted nor received.

As used within this document, the term “communicate” is intended to include transmitting and/or receiving. This may be particularly useful in claims when describing the organization of data that is being transmitted by one device and received by another, but only the functionality of one of those devices is required to infringe the claim. Similarly, the exchange of data between a network controller and a mobile device (both devices transmit and receive during the exchange) may be described as ‘communicating’, when only the functionality of one of those devices is being claimed.

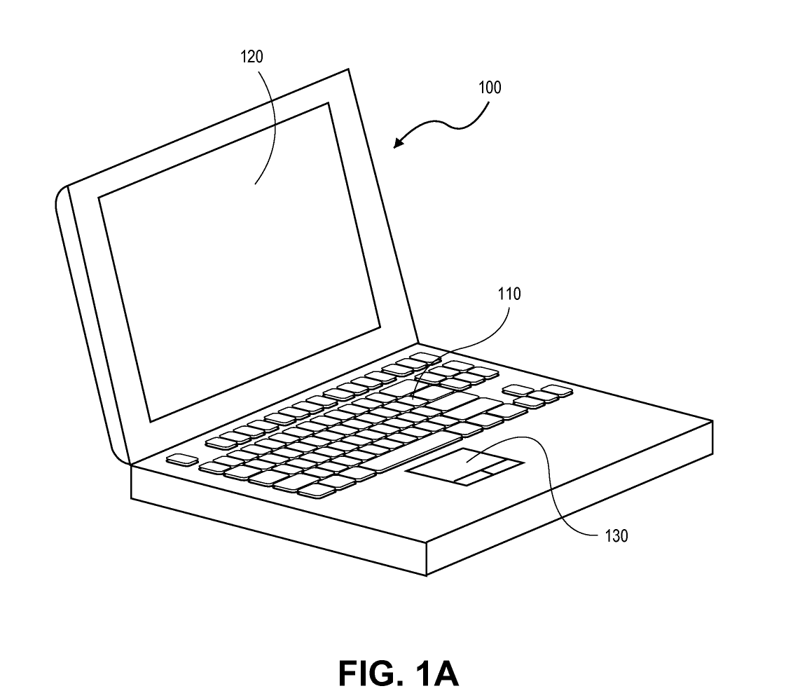

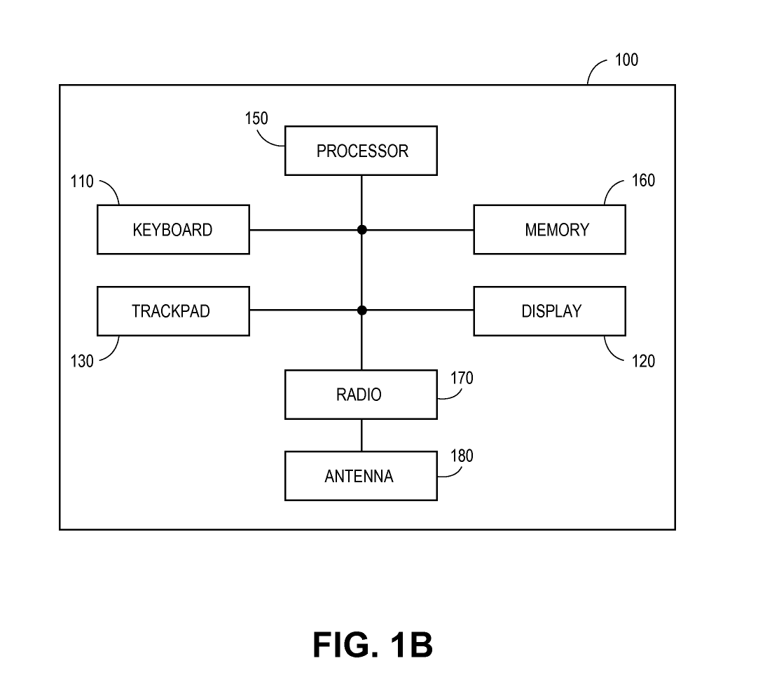

FIG. 1A shows a communications device, according to an embodiment of the invention. Device 100 is shown as a typical notebook computer, with a keyboard 110, a display 120, and a trackpad 130, but device 100 may be any device, with any shape and configuration, that utilizes NFC wireless communications and has a keyboard.

FIG. 1B shows functional components within a wireless communications device, according to an embodiment of the invention. In addition to keyboard 110, display 120, and trackpad 130 as shown in FIG. 1A, wireless communications device 100 is also shown with processor 150, memory 160, radio 170, and radio antenna 180. Although device 100 is shown with one each of these items, more than one of any of these items may be included in wireless device 100.

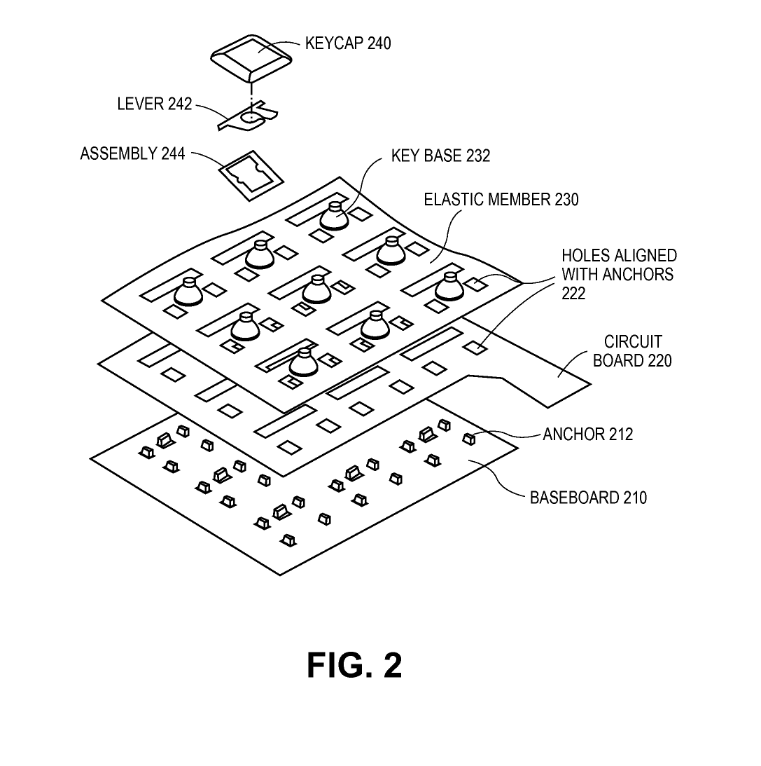

FIG. 2 shows some components of a low profile keyboard assembly, according to an embodiment of the invention. At the bottom may be a baseboard 210, typically made of metal or at least containing a planar sheet of metal. Baseboard 210 is also shown with a number of anchors 212, which may be used to align the subsequent layers with the baseboard. Circuit board 220 may contain the wiring, integrated circuit(s), and other electrical or electronic components used in the keyboard. Elastic member 230 may be a flexible substrate on which are mounted various key bases 232. A keycap 240, lever 242, and assembly 244 may be connected to each key base to allow the downward movement of a keycap to be detected. By inserting anchors 212 through holes 222 in both the circuit board 220 and elastic member 230, the various layers of this assembly may be accurately aligned during assembly. Although this embodiment shows a particular arrangement of these parts, this is only an example. Other shapes, parts, configurations, etc. may also be used. The main purpose of this figure is to show the existence of a metal baseboard in the keyboard assembly. To avoid excessive clutter in this figure, other details of baseboard 210 are not shown here, but are described later in more detail.

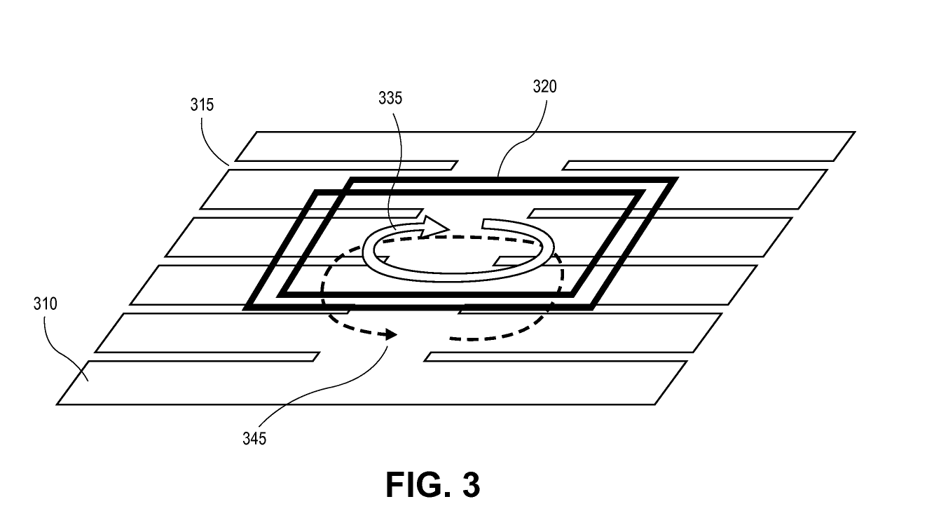

FIG. 3 shows a baseboard and nearby antenna, according to an embodiment of the invention. Baseboard 310 in FIG. 3 may be the same as baseboard 210 in FIG. 2, but baseboard 210 is drawn to show the anchors that are intended to enable accurate alignment in the assembly, while baseboard 310 is drawn to show slots 315 in the baseboard. Within this document, a ‘slot’ is an opening that penetrates through the entire depth of the planar-shaped metal, and has a length much longer than its width. A slot may typically have a width that is uniform throughout the length of the slot, but this should not be interpreted as a limitation on the shape of a slot.

Antenna 320 is shown as a multiple-loop antenna, although other configurations may be used instead. Two loops are shown for simplicity of illustration, but one, three, or more loops may also be used. Antenna 320 is shown to have a rectangular shape, but it may have any other feasible shape, such as but not limited to square, circle, oval, or a more complex shape. In a typical NFC antenna in a notebook computer, the plane of antenna 320 may be parallel to the plane of baseboard 310, and it may be spaced within 2 centimeters either above (as shown) or below the baseboard. When current is induced in the loops (shown by clockwise arrow 335), the magnetic field created by this current may induce eddy currents in the opposite direction (shown by the counter clockwise arrow 345) in the metal baseboard. In a solid baseboard, this eddy current could be high, and it could therefore create significant reduction in the signal emanating from the antenna as measured outside the device chassis.

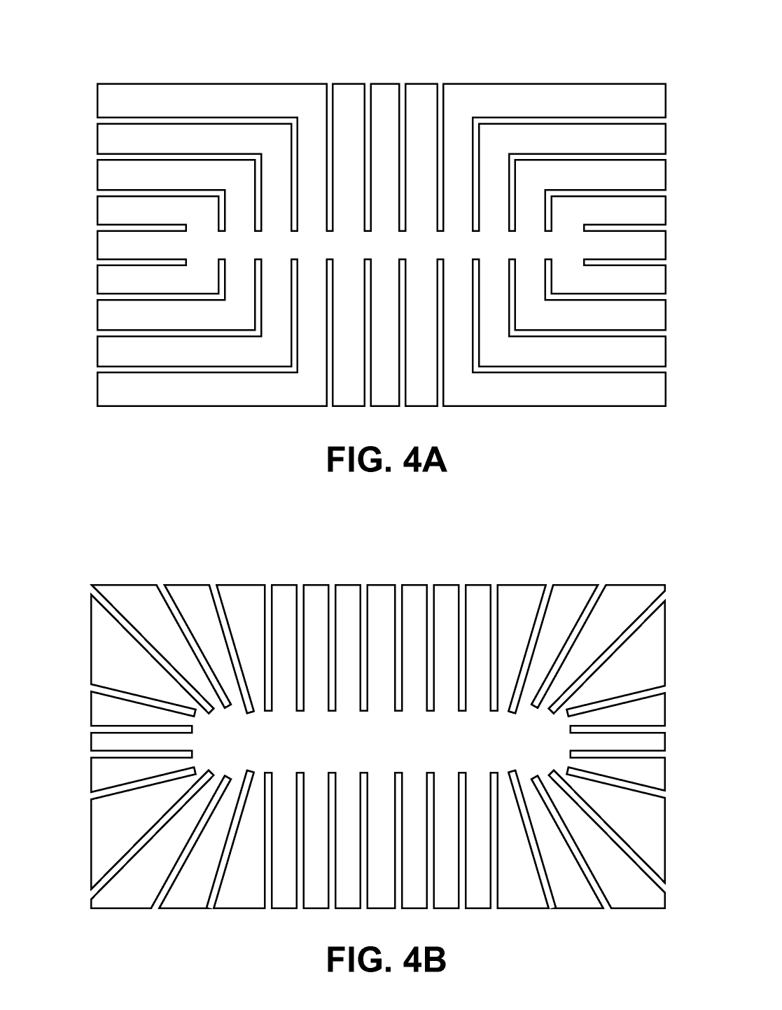

The purpose of slots 315 is to disrupt this eddy current. The disruption can theoretically be maximized if the direction of each slot is perpendicular to the direction of the eddy current at each location of the slot. The straight slots in FIG. 3 are all parallel to the long side of the rectangular loops, so that the greatest effective disruption is possible from the flux induced by two opposing sides of the antenna, but less effective for flux induced by the other two sides. Accordingly, these slots may be configured in other patterns to make more efficient use of this disruptive effect, such as the patterns shown in FIGS. 4A, 4B.

FIGS. 4A, 4B show two different patterns of slots created in a planar metal sheet to be located near an NFC antenna, according to two embodiments of the invention. Each pattern could be effectively used with the rectangular-shaped antenna shown in FIG. 3, with the plane of the antenna parallel to the plane of the metal sheet, and with the center of the antenna positioned near the center of the slot pattern. In each case at least half of the slots are each approximately perpendicular to the nearest side of the antenna, and therefore approximately perpendicular to the eddy current induced by the flux from the nearest side of the antenna.

Because the sharp corners of the rectangular antenna can result in a somewhat unpredictable transition in the flux created near those corners, it may not be feasible to exactly match the direction of the slots near the corners to the eddy currents in those areas. The pattern of FIG. 4B tries to approximate the effects of this transition, while the pattern of FIG. 4A ignores this transition in the interest of design simplicity. In some embodiments, at least half of the slots may each contain a portion of the slot that is perpendicular to the part of the antenna nearest that portion. The terms ‘perpendicular’ and ‘parallel’, when used in this document, should be interpreted as ‘approximately’ perpendicular and parallel, due to the inexact nature of magnetic flux, eddy currents, and even the tolerances of manufacturing and assembly.

The slots in FIGS. 4A and 4B are shown to extend to the edges of the metal sheet. This may improve the reduction of eddy current, but may result in structural weakness in the metal sheet, especially around the edges. In some embodiments, some or all of the slots may terminate before reaching the edge (not shown in the figures but easily visualized), resulting in stronger structural strength while sacrificing some effectiveness. In a particular embodiment, at least half the slots extend to the edge of the metal sheet, while the other slots do not. The relative merits of this tradeoff may be made on a case-by-case design basis.

The slotted patterns may be used in any situation in which a metal sheet is placed in close proximity to an NFC antenna. The example shown in FIG. 2, which should not be inferred as a limitation, is for a metal baseboard used in a keyboard assembly, with the NFC antenna placed near the baseboard. In a typical application the antenna may be placed below the baseboard (e.g., on the opposite side of the baseboard from the keys). In other embodiments, the antenna may be placed above the baseboard. In a version of this, the antenna may be formed on the circuit board, either as an attached wired antenna or as a conductive trace attached by being deposited on the circuit board.

The horizontal location of the antenna with respect to the keyboard may be varied according to design choice, but the short range of NFC communications (a few centimeters) may dictate this choice. For example, if the antenna is placed beneath the center of a full size keyboard in a notebook computer, the device to be communicated with may need to be held slightly above the center of the keyboard to be within communications range. On the other hand, if the keyboard opening extends near an edge of the notebook computer, the antenna may be placed close to that edge, even if the location of the actual keys doesn't extend that far. This would allow another device to be placed next to that edge and be within communications range.

These same principles may be applied to other types of devices, such as tablet computers and smart phones, in which a planar metal piece may be placed in a position to potentially interfere with the magnetic flux emanating from the NFC antenna. Such devices may or may not have a conventional keyboard, in which case the opening in the chassis may be for something other than a keyboard.

Although the metal baseboard in the foregoing description may be metal throughout, the same principles may be applied to sheets that are only partial metal. For example, a composite sheet made by layering metal with non-metal may be used. In that embodiment, the slots may be placed only in the metal layer, while the non-metal layer may remain solid, thus retaining structural strength while still benefiting from the slots in the metal. The metal layer may be attached to the underlying non-metal layer through any feasible means, such as using an adhesive. In some embodiments, the metal layer may be deposited on the non-metal layer through masked deposition, full deposition followed by etching, or through other deposition techniques.

The foregoing description is intended to be illustrative and not limiting. Variations will occur to those of skill in the art. Those variations are intended to be included in the various embodiments of the invention, which are limited only by the scope of the following claims.

What is claimed is:

1. A wireless communications device comprising:
a processor, a memory, a radio, an antenna configured for communicating using near field communication, and a keyboard assembly, the keyboard assembly containing a planar sheet of metal positioned near the antenna;
wherein the sheet of metal contains multiple slots for disrupting eddy currents induced in the sheet of metal by magnetic emanations from the antenna.

2. The device of claim 1, wherein at least half of the slots have a portion oriented in a direction perpendicular to a nearest part of the antenna.

3. The device of claim 1, wherein the antenna is configured with a rectangular shape.

4. The device of claim 1, wherein at least half of the slots each extends to an edge of the sheet of metal.

5. The device of claim 1, wherein the planar sheet of metal is attached to a planar sheet of non-metal.

6. The device of claim 5, wherein the planar sheet of non-metal does not include the slots.

7. The device of claim 1, wherein the keyboard assembly includes a circuit board, and the circuit board includes the antenna.

8. The device of claim 1, wherein the device is a device selected from a list consisting of a notebook computer, tablet computer, and a smart phone.

9. The device of claim 1, wherein a plane of the planar sheet of metal is positioned parallel to a plane of the antenna.

10. A keyboard assembly comprising:
a plurality of keys;
a circuit board coupled to the plurality of keys;
a baseboard coupled to the circuit board and having a planar sheet of metal, wherein the planar sheet of metal includes multiple slots configured to disrupt eddy current induced by magnetic emanations from a nearby antenna for near field communication communications.

11. The keyboard assembly of claim 10, wherein at least half the slots are configured to be perpendicular to a nearest portion of the antenna, the antenna to have a particular size, shape, and distance from the planar sheet of metal.

12. The keyboard assembly of claim 10, wherein the planar sheet of metal is attached to a planar sheet of non-metal.

13. The keyboard assembly of claim 12, wherein the planar sheet of non-metal does not include the slots.

14. The keyboard assembly of claim 10, wherein a least some of the slots extend to an edge of the planar sheet of metal.

15. A device comprising:
a planar sheet of metal containing openings shaped like slots;
wherein at least half of the slots each has at least a portion configured to be perpendicular to a nearest portion of a nearby antenna for near field communication communications.

16. The device of claim 15, wherein at least some of the slots extend to an edge of the planar sheet of metal.

17. The device of claim 15, wherein the planar sheet of metal is attached to a planar sheet of non-metal.

18. The device of claim 17, wherein the planar sheet of non-metal does not include the slots.
